(19) United States
(12) Patent Application Publication
(10) Pub. No.: US 2008/0218257 A1
(43) Pub. Date: Sep. 11, 2008

(54) Distributed track-and-hold amplifier

(76) Inventor: Jaesik Lee, Bridgewater, NJ (US)

Correspondence Address: Lucent Technologies Inc., Docket Administrator - Room 3J-219, 101 Crawfords Corner Road, Holmdel, NJ, 07733-3030, US

(21) Appl. No.: 11/714,009

(22) Filed: Mar. 5, 2007

(51) Int. Cl. G11C 27/02

(52) U.S. Cl. 327/561

(57) ABSTRACT

An apparatus includes an analog input buffer having one or more inputs and one or more outputs, a plurality of differential track-and-hold stages, one or more input transmission lines, and one or more output transmission lines. Each track-and-hold stage has one or more inputs and one or more outputs. The one or more input transmission lines connect the one or more outputs of the differential analog input buffer to the inputs of the track-and-hold stages. The one or more output transmission lines connect to the outputs of the track-and-hold stages. The connections to the inputs of the stages are spatially distributed along the one or more input transmission lines, and connections to the outputs of the stages are spatially distributed along the one or more output transmission lines.

This application claims the benefit of U.S. provisional patent application No. 60/______, entitled “DISTRIBUTED TRACK-AND-HOLD AMPLIFIER” (Docket No. Lee 4), filed by Jaesik Lee on Feb. 10, 2007.

The U.S. Government has a paid-up license in this invention and the right in limited circumstances to require the patent owner to license to others on reasonable terms as provided for by the terms of contract No. HR0011-05-C-0153 awarded by DARPA.

### BACKGROUND

1. Field of the Invention

The invention relates generally analog amplifiers and receiver circuits.

2. Discussion of the Related Art

Advanced digital receivers can function as robust, scalable, and flexible signal detector as well as operating as compensators of signal distortions produced during transmission. In the future, such advanced digital receivers may require analog-to-digital converters (ADCs) with wide bandwidths and high dynamic ranges. For example, digital optical receivers for data rates of 10 or more giga-bits per second (Gb/s) may need ADCs capable of handling instantaneous signal bandwidths of greater than 10 giga-Hertz (GHz) and capable of providing low resolutions, e.g., less than about 5 bits.

In advanced digital receivers, it is often desirable to have a broadband track-and-hold amplifier (THA) configured to acquire samples of the input waveform for quantization by the ADC. In such configurations, the ADC can typically quantize samples of input waveform with less interference to and less dependence on specific input line properties. In such configurations, a broadband THA can reduce linearity degradations that are associated with long settling times and nonlinear parasitics. In particular, the use of such a broadband THA can reduce timing jitter.

Recently, progress has been made towards fabricating monolithic THAs having smaller feature sizes based on silicon-germanium (SiGe) and indium-phosphide (InP) technologies. Such monolithic THAs can provide both high sampling rates and low resolutions.

### BRIEF SUMMARY

Various embodiments provide distributed track-and-hold amplifiers (DTHAs) and methods for operating DTHAs. The DTHAs have substantially parallel signal processing paths, which can enhance dynamical ranges of such DTHAs.

One embodiment features an apparatus. The apparatus includes an analog input buffer having one or more inputs and one or more outputs, a plurality of differential track-and-hold stages, one or more input transmission lines, and one or more output transmission lines. Each track-and-hold stage has one or more inputs and one or more outputs. The one or more input transmission lines connect the one or more outputs of the differential analog input buffer to the inputs of the track-and-hold stages. The one or more output transmission lines connect to the outputs of the track-and-hold stages. The connections to the inputs of the stages are spatially distributed along the one or more input transmission lines, and connections to the outputs of the stages are spatially distributed along the one or more output transmission lines.

In some embodiments of the apparatus, the analog input buffer is differential and has a pair of inputs and a pair of outputs and each track-and-hold stage is a differential and has a pair of inputs and a pair of outputs. In such embodiments, the one or more input transmission lines includes a pair of input transmission lines, and the one or more output transmission lines includes a pair of output transmission lines.

One embodiment features a method of operating a track-and-hold amplifier. The method includes transmitting an input waveform to one or more input transmission lines and charging a plurality of hold capacitors by connecting the capacitors to points spatially distributed along the one or more input transmission lines while performing the transmitting. The method also includes disconnecting the charged hold capacitors from the one or more input transmission lines such that the hold capacitors are connected along one or more output transmission lines.

In some embodiments of the method, the one or more input transmission lines includes a parallel pair of input transmission lines, and the one or more output transmission lines includes a parallel pair of output transmission lines.

### BRIEF DESCRIPTION OF THE DRAWINGS

FIG. 1 is a circuit block diagram illustrating an exemplary embodiment of three-stage distributed track-and-hold amplifier (DTHA);

FIG. 2A is a circuit diagram illustrating an exemplary lumped analog input buffer for the DTHA shown in FIG. 1;

FIG. 2B is a circuit diagram illustrating an exemplary distributed analog input buffer for the DTHA shown in FIG. 1;

FIG. 3 is a circuit diagram that illustrates the operation of a switched input, hold capacitor, and output buffer (SIHCOB) stage, e.g., as shown in the DTHA of FIG. 1;

FIG. 4 is a circuit diagram illustrating a specific embodiment of a differential SIHCOB stage for the DTHA shown in FIG. 1;

FIG. 5 is a circuit diagram for a specific embodiment of a distributed clock buffer for the DTHA shown in FIG. 1;

FIG. 6 is a flow chart illustrating a method of operating a DTHA, e.g., the DTHA of FIG. 1; and

FIG. 7 is a circuit block diagram illustrating an embodiment of a DTHA that has distributed input and clock buffers and that may be also be operated according to the method of FIG. 6.

In the various Figures, like reference numbers indicate elements with similar or the same function.

### DETAILED DESCRIPTION OF ILLUSTRATIVE EMBODIMENTS

Herein, various circuit blocks have differential inputs that will generally be indicated as IN_{N} and IN_{P} and have differential outputs that will generally be indicated as OUT_{N} and OUT_{P}.

Below, various distributed track-and-hold amplifiers (DTHAs) are described. In various embodiments DTHAs can provide wider bandwidths, higher gain bandwidth products, and better linearity than various non-distributed track-and-hold amplifiers. Even though DTHAs typically have complex designs and may suffer from higher noise levels and power dissipation levels, the above-described advantages of DTHAs may outweigh the disadvantages of such distributed circuit devices. In addition, said DTHAs may be fabricated using conventional integrated circuit processing technologies.

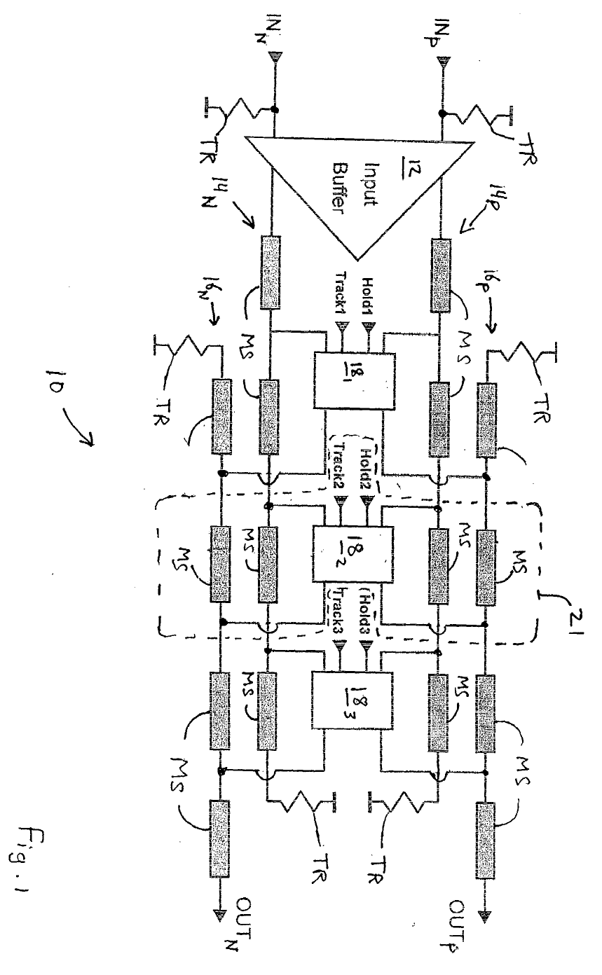

FIG. 1 illustrates an exemplary three-stage DTHA 10. The DTHA includes a differential analog input buffer 12; a pair of matched input transmission lines 14_{N}, 14_{P}; a pair of matched output transmission lines 16_{N}, 16_{P}; and three substantially identical, differential, switched input, hold capacitor, and output buffer (SIHCOB) stages 18₁, 18₂, 18₃. The differential analog input buffer 12 receives the input waveform from the differential inputs IN_{N}, IN_{P} of the DTHA 10. The input transmission lines 14_{N}, 14_{P} connect, in parallel, the paired differential outputs of the differential analog input buffer 12 to paired differential inputs of the SIHCOB stages 18₁, 18₂, 18₃ in a substantially parallel arrangement. Each input transmission line 14_{N}, 14_{P} includes, e.g., a sequence of substantially identical microstrip segments, e.g., 50 ohm microstrips. The output transmission lines 16_{N}, 16_{P} connect, in parallel, each pair of differential outputs of the SIHCOB stages 18₁, 18₂, 18₃ to the paired differential outputs OUT_{N}, OUT_{P} of the DTHA 10. Each output transmission line 16_{N}, 16_{P} also includes, e.g., a sequence of substantially identical microstrips, e.g., 50 ohm microstrip segments (MSs). For the transmission lines 14_{N}, 14_{P}, 16_{N}, 16_{P}, exemplary 50 ohm microstrip segments, MS, may be formed of 2.8 micrometer thick aluminum metallization strips wherein the strips are about 200 micrometers long, are about 15 micrometers wide, and are spaced about 30 micrometers from a metal ground plane. For such exemplary microstrip segments, MS, the input transmission lines 14_{N}, 14_{P} and the output transmission lines 16_{N}, 16_{P} should be spaced apart by at least 150 micrometers to minimize couplings there between. The ends of the input transmission lines 14_{N}, 14_{P} and the output transmission lines 16_{N}, 16_{P} include termination resistors (TRs) that are configured to minimize signal reflections on the transmission lines 14_{N}, 14_{P}, 16_{N}, 16_{P}. For example, the termination resistors, TR, may be 50 ohm resistors for standard transmission lines, in which, e.g., the microstrip segments, MS, have 50 ohm impedances. Similarly, the matched inputs of the differential analog input buffer 12 include termination resistors TR that are suitable to minimize reflections of received signals, e.g., 50 ohm resistors.

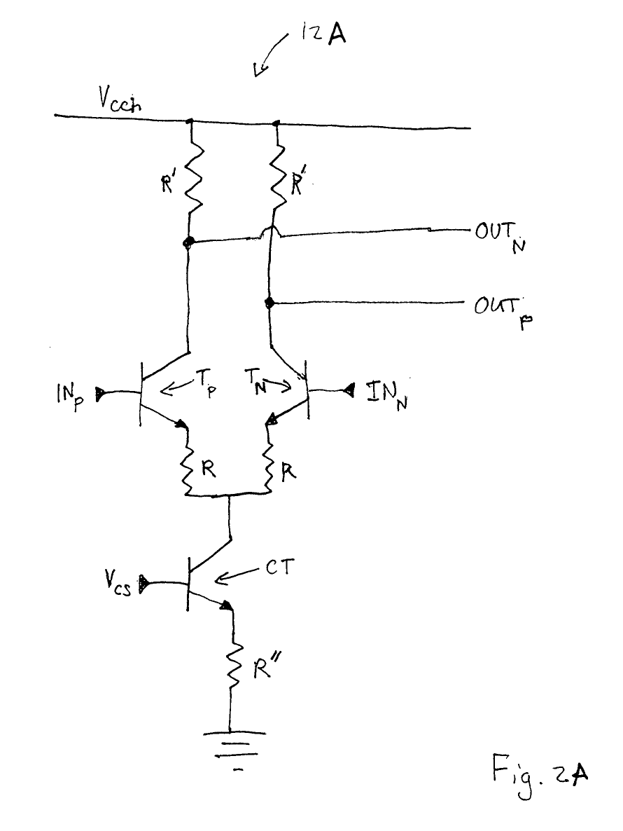

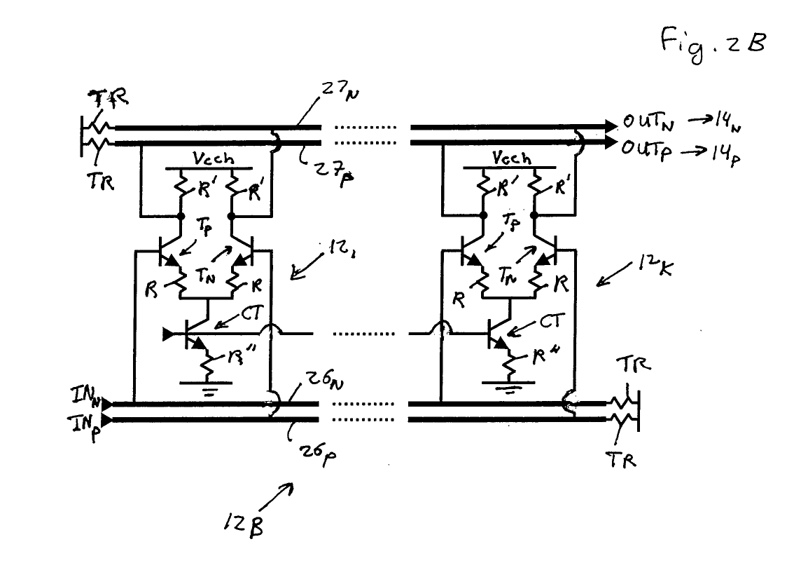

FIG. 2A is a block diagram for a lumped embodiment 12A of the differential analog input buffer 12 shown in FIG. 1. The lumped differential analog input buffer 12A is an emitter-degenerated differential amplifier. The differential amplifier 12A has a low gain, e.g., unit or lower gain, and a low output impedance. The input of the differential amplifier 12A may also connect to the output of a pair of emitter followers (not shown).

The differential amplifier 12A includes matched bipolar transistors T_{N}, T_{P} with bias resistors R, R′ and an active current source that includes a transistor CT and a resistor R″. The resistors R, R′ and supply voltage Vcch, e.g., a 4 volt supply, are configured so that the differential amplifier 12A has the low gain and low output impedance. The resistances of the load resistors R′ may match the image impedance of the distributed SIHCOB stages 18₁, 18₂, 18₃, e.g., 50 ohms, so that signal reflections between the lumped differential analog input buffer 12A and the SIHCOB stages 18₁, 18₂, 18₃ are reduced. The transistor CT and bias resistor R″ form an active current source whose output current is controllable by a control voltage Vcs so that the biasing current is adjustable in the differential lumped analog input buffer 12B. The active current source is able to provide a biasing current, e.g., of about 16 milli-amps (ma), e.g., a bias current that is large enough to turn off emitter followers of the SICHOB stages 18₁, 18₂, 18₃ during hold periods.

FIG. 2B illustrates a distributed embodiment 12B of the differential analog input buffer 12 shown in FIG. 1. The distributed differential analog input buffer 12B includes a pair of substantially identical transmission lines (26_{N}, 26_{P}), a pair of substantially identical transmission lines (27_{N}, 27_{P}), and a sequence of K emitter-degenerated differential amplifier stages 12₁, . . . , 12_{K}. Here, K may be, e.g., 2, 3, 4, or 5. Each differential amplifier stage 12₁, . . . , 12_{K} connects between the input transmission lines 26_{N}, 26_{P} and the output transmission lines 27_{N}, 27_{P}. The paired inputs of the distributed differential analog input buffer 12B may also connect to the outputs of a matched pair of emitter followers (not shown).

Each transmission line 26_{N}, 26_{P}, 27_{N}, 27_{P} may be constructed of a sequence of microstrip MS segments as in the transmission lines 14_{N}, 14_{P}, 16_{N}, 16_{P} of FIG. 1.

Each differential amplifier stage 12₁, . . . , 12_{K} has a low gain, e.g., unit or lower gain, and a low output impedance. Each differential amplifier stage 12₁, . . . , 12_{K} includes a pair of matched bipolar transistors T_{N}, T_{P} with associated bias resistors R, R′ and an active current source that includes a transistor CT and a resistor R″. The bases and collectors of the bipolar transistors T_{N}, T_{P} function as differential inputs and differential outputs, respectively. The resistors R, R′ and supply voltage Vcch, e.g., a 4 volt supply, are configured so that the differential amplifier 12A has both a low gain and a low output impedance. The resistors R′ may be selected to reduce signal reflections on the output transmission lines 27_{N}, 27_{P}. In each stage, the transistor CT and resistor R″ form an active current source that functions as already described with respect to the differential amplifier 12A of FIG. 2A.

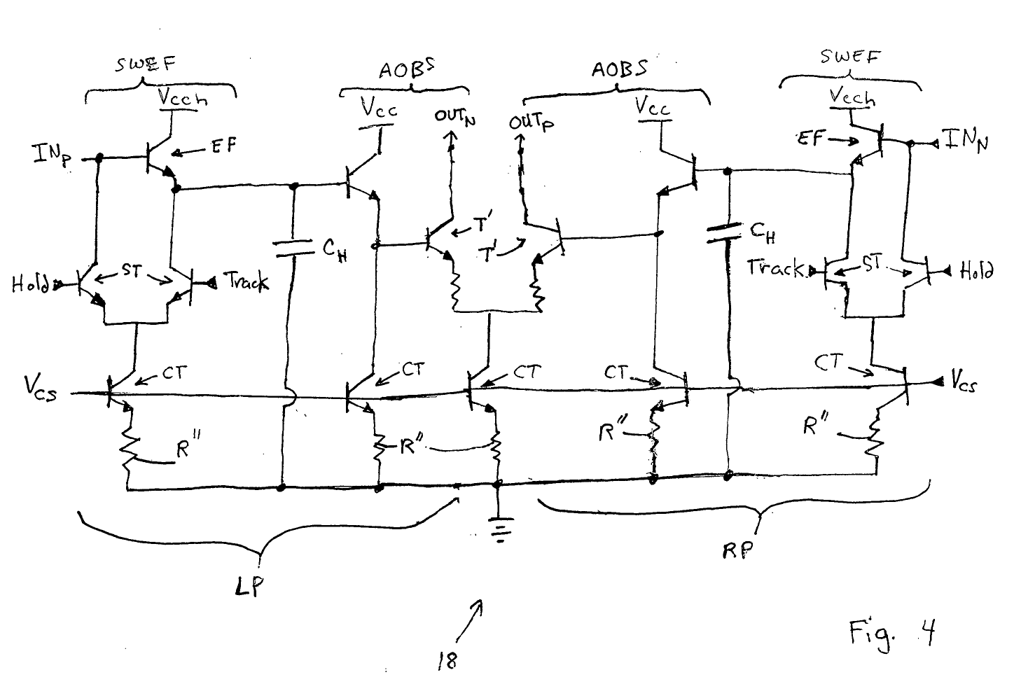

FIG. 4 is a block diagram of an exemplary embodiment for a SIHCOB stage 18, e.g., the identical SIHCOB stages 18₁, 18₂, 18₃ of the DTHA of FIG. 1. The SIHCOB stage 18 includes substantially identical left and right portions, i.e., LP and RP, that produce output signals OUT_{N} and OUT_{P} in response to respective IN_{N} and IN_{P} input signals via substantially identical processing. Due to the processing by the substantially identical left and right portions LP and RP, the SIHCOB stage 18 produces a differential pair of output signals OUT_{N} and OUT_{P} from the received differential pair of input signals IN_{N} and IN_{P}. The blocks of the left and right portions LP, RP of the SIHCOB stage 18 are controlled by an array of five active current sources, i.e., the bipolar transistors CT. Again, the active current sources CT provide a manner for flexibly controlling the bias currents in the blocks of the SIHCOB stage 18, i.e., in a manner responsive to the value of a control signal voltage Vcs that is applied to the bases of the bipolar transistors CT.

Each of the left and right portions LP, RP of the SIHCOB stage 18 includes a switched emitter follower (SWEF) stage, a hold capacitor C_{H}, and an analog output buffer stage (AOBS). Each SWEF stage includes a bipolar transistor configured as an emitter follower (EF) and a set of substantially identical pair of emitted-degenerated switching transistors (STs). The emitter follower EF is connected to generate from the input signal, i.e., IN_{P} or IN_{N}, an output voltage that charges the hold capacitor C_{H} during the track mode. Each emitter follower may be configured to use a relatively high bias current, e.g., about 5.4 milli-amps, to suppress signal dependent modulation of the base-emitter voltage therein. For example, the supply voltage Vcch may be about 4 volts. Each pair of switch transistors ST is connected to turn on the emitter follower EF in response to receiving from a clock buffer (not shown) an appropriate “Track and Hold” signals and to turn OFF the emitter follower EF in response to receiving from the clock buffer appropriate “Track and Hold” signals. Thus, the pair of switching transistors STs cause the emitter follower EF to charge the hold capacitor C_{H} in a manner that is responsive to the input signal IN_{P} or IN_{N} during track periods and to disconnect the input signal from the hold capacitor C_{H} during the alternating hold periods. To obtain a large bandwidth and good hold period performance, the hold capacitors C_{H} may be selected to have capacitances that ensure linear operation over a large range, e.g., a total hold capacitance of about 200 fF including parasitic hold capacitances may be adequate. Each analog output buffer stage AOBS includes two bipolar transistors T′ that are connected as a Darlington pair. The base of each Darlington pair connects to one plate of a corresponding one of the hold capacitors C_{H} so that the Darlington pair provides during the track periods an output signal OUT_{P} or OUT_{N} at its collector where the output signal OUT_{P} or OUT_{N} measures the charge on the corresponding hold capacitor C_{H}. For each analog output buffer stage AOBS, the supply voltage Vcc may be, e.g., about 3.3 volts. The bipolar transistors T′ of the analog output buffers, AOBS, connect via the output transmission lines 16_{N}, 16_{P} to a circuit device, e.g., an analog-to-digital converter, which provides the biasing for these bipolar transistors T′.

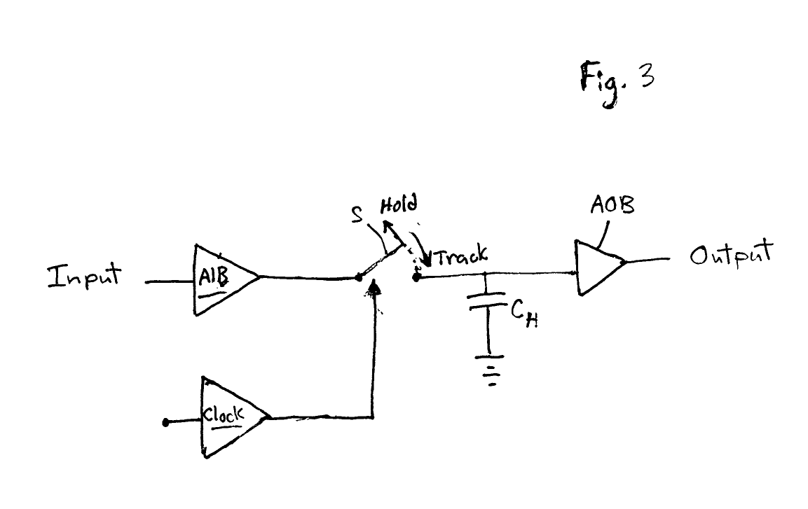

FIG. 3 is a block diagram that illustrates the operation of the left and right portions LP, RP of the differential SIHCOB stage 18 as show in FIG. 4. Functionally, each portion LP, RP of the SIHCOB stage 18 includes an analog input buffer (AIB), a switch (S), a hold capacitor C_{H}, and an analog output buffer (AOB). The switch (S) is closed during track periods and is open during the hold periods, wherein the alternating track and hold periods are produced by the sequence of Track and Hold signals output by a clock buffer CB. During each track period, the applied track and hold signals cause the switch S to be closed thereby enabling the signal at the analog input buffer to adjust the charge stored on the hold capacitor C_{H}. Each track period ends when the applied track and hold signals cause the switch S to open thereby starting a hold period. During each hold period, the AOB outputs at the Output an analog output signal that is representative of the charge stored on the hold capacitor C_{H}. The analog output signal can then, be used as the input signal for an analog-to-digital converter in a manner that is substantially decoupled from the input to the SIHCOB stage 18. That is, the analog output signal can be sampled to produce a digital value corresponding to the stored charge on the hold capacitor C_{H}.

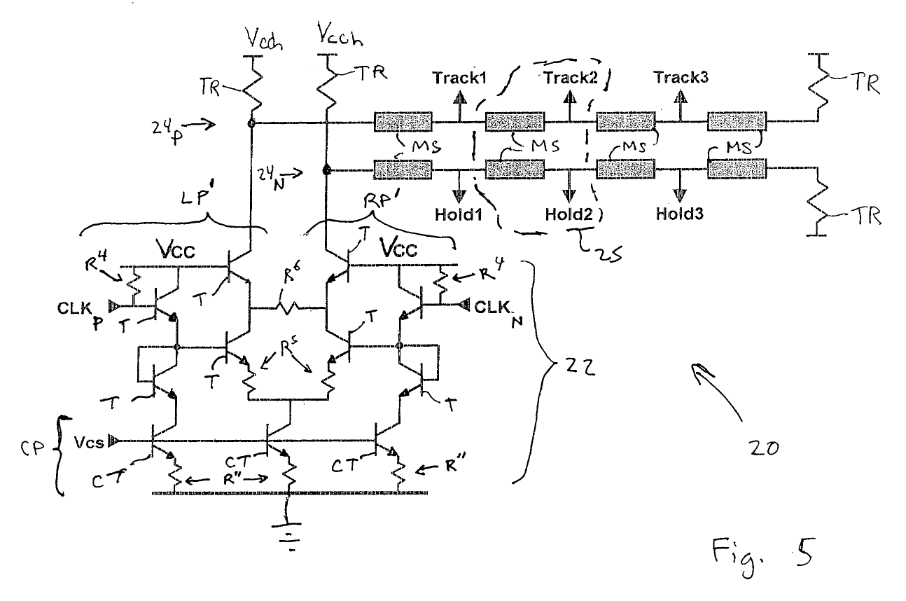

FIG. 5 is a block diagram of an exemplary distributed clock buffer 20 for the DTHA 10 of FIG. 1. The distributed clock buffer 20 includes a differential lumped clock core 22 and a pair of substantially identical output transmission lines 24_{N}, 24_{P}, which are driven by the differential lumped clock core 22. The differential lumped clock core 22 has substantially identical left and right portions LP′, RP′ and has a control portion (CP). The left and right portions LP′, RP′ have networks of bipolar transistors T and resistors R⁴, R⁵, R⁶ and include cascode transistor architectures. The differential lumped clock core 22 may be biased by the same supply voltage Vcch that biases the differential analog input buffer 12 of FIG. 1, e.g., as shown in FIG. 2A or 2B. Each output transmission line 24_{N}, 24_{P} includes a series of substantially identical microstrip segment, MS. In the transmission lines 24_{N}, 24_{P}, each microstrip segment, MS, has a length matched to the microstrip segments, MS, of the input transmission lines 14_{N}, 14_{P} of FIG. 1 so that suitable delays are produced between the Track1, Track2, and Track3 signals and between the Hold1, Hold2, and Hold3 that are output by the output transmission lines 24_{N}, 24_{P} to the SICHOB stages 18₁, 18₂, 18₃ of FIG. 1. For example, the microstrip segments, MS, of FIG. 5 may be substantially identical to the microstrip segments, MS, of the input transmission lines 14_{N}, 14_{P} of FIG. 1. In particular, the delays along the transmission lines 24_{N}, 24_{P} are configured so that the (Track1, Hold1), (Track2, Hold2), and (Track3, Hold3) signal pairs produce suitably timed track and hold periods for the three SIHCOB stages 18₁, 18₂, 18₃ of FIG. 1. The control portion CP includes bipolar transistors CT that function as current sources, which are again responsive to the control signal Vcs.

In other embodiments, the DTHA 10 may have a different number of SIHCOB stages 18_{N} and transmission lines 14_{N}, 14_{P}, 16_{N}, 16_{P} with different numbers of microstrip segments, MS, than shown in FIG. 1. For example, the portion 21 of the DTHA of FIG. 1 and the portion 25 of the transmission line of FIG. 5 may be absent in some embodiments thereby producing a DTHA with only two SIHCOB stages 18₁, 18₃. Alternatively, the portion 21 of the DTHA of FIG. 1 and the portion 25 of the transmission line of FIG. 5 may be, e.g., repeated in some embodiments thereby producing a DTHA with more than three SIHCOB stages 18_{N}.

Monolithic examples of the DTHA 10 of FIG. 1 may be fabricated with conventional 0.18 micrometer (μm) SiGe BiCMOS technologies.

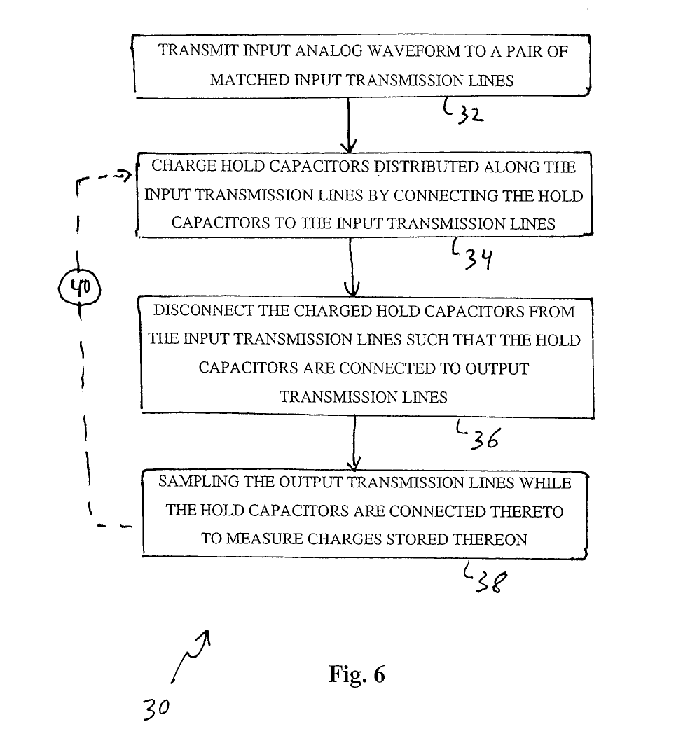

FIG. 6 is a flow chart illustrating a method 30 of processing a received analog waveform to analog-to-digital convert the waveform, e.g., using the DTHA of FIG. 1. The method 30 includes transmitting the received analog waveform to a pair of matched input transmission lines in parallel, e.g., the input transmission lines 14_{N}, 14_{P} of FIG. 1 (step 32). Distributed along the length of each pair of input transmission lines are connections to the inputs of a sequence of analog track-and-hold stages, e.g., the differential SIHCOB stages 18₁, 18₂, 18₃ of FIG. 1. Since the track-and-hold stages are distributed along the transmission lines, different ones of these stages may receive the input analog waveform after different transmission delays. The method 30 includes charging one or two hold capacitors, e.g., capacitors C_{H}, in each of the track-and-hold stages by sampling the analog waveform transmitted thereto via the input transmission lines (step 34). The charging charges the hold capacitors of the track-and-hold stages to charge levels indicative of the magnitude of the analog waveform received in the track-and-hold stages via the input transmission lines. The sampling step 34 may be performed, e.g., in response to receiving appropriate “track” signals in the track-and-hold stages from a clock, e.g., clock buffer 20 of FIG. 5. Such track signals could cause switches to connect the hold capacitors of the track-and-hold stages to the input transmission lines thereby adjusting the charges stored on the hold capacitors, e.g., as performed in the SIHCOB stage 18 of FIG. 4. The method 30 includes disconnecting the charged hold capacitors from the input transmission lines, e.g., via opening switches in the track-an-hold stages (step 36). The opening of said switches may be performed in response to receiving appropriate “hold” signals from a clock, e.g., the clock buffer 20 of FIG. 5. While being disconnecting for the input transmission lines, the hold capacitors are connected to a pair of matched output transmission lines with parallel located outputs, e.g., the lines 16_{N}, 16_{P} of FIG. 1. The method 30 may include sampling the hold capacitors via the output transmission lines, i.e., while the hold capacitors are connected thereto and are disconnected from the input transmission lines to measure a charge stored on the hold capacitors, i.e., to obtain a sampling measure of the received analog waveform (step 38). For example, such sampling may be a sampling step for the analog-to-digital conversion of the received analog waveform. Such sampling steps can obtain a temporal sequence of digital measurements of the values of the received waveform at the times that the hold capacitors were charged by said waveform. During analog-to-digital conversion, a loop 40 may be performed to repeat steps 34, 36, and 38 thereby performing a temporal sequence of sampled values of the received analog waveform.

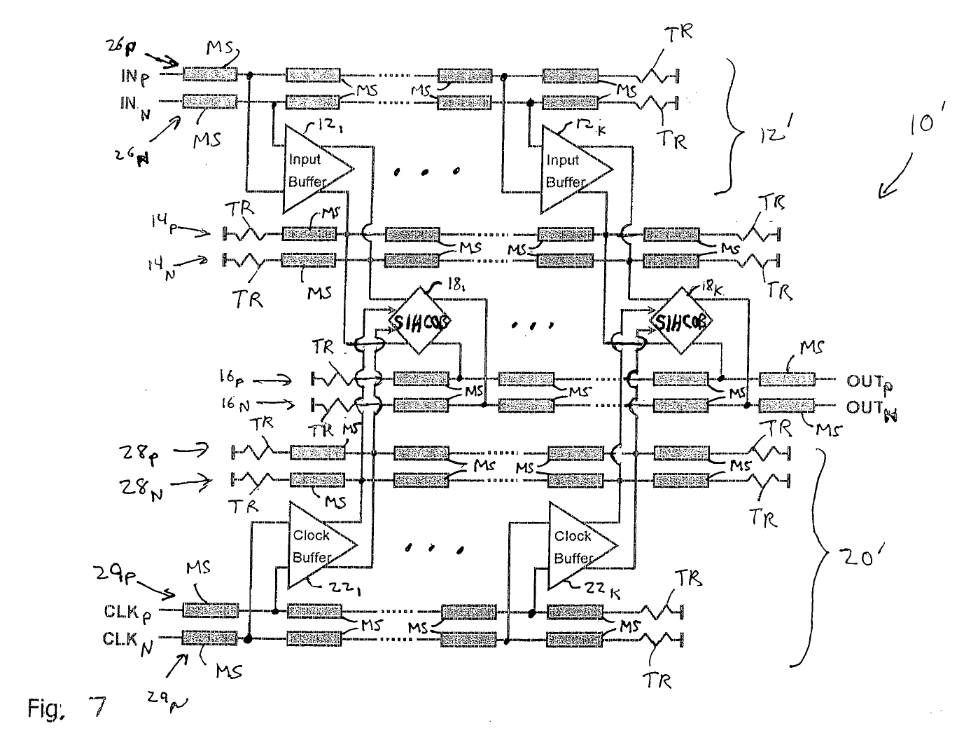

FIG. 7 illustrates a general embodiment 10′ for a DTHA with a distributed analog input buffer 12′ that may also be operated by method 30 of FIG. 6. The DTHA 10′ includes a distributed differential analog input buffer 12′; a pair of substantially identical (K+1)-segment input transmission lines 14_{P},14_{N}; a pair of substantially identical (K+1)-segment output transmission lines 16_{P},16_{N}; K SIHCOB stages 18₁, . . . , 18_{K}; and a distributed clock buffer 20′. The distributed differential analog input buffer 12′ includes a pair of substantially identical (K+1)-segment transmission lines 26_{P}, 26_{N} and K lumped differential analog input buffers 12₁, . . . , 12_{K}. Here, K is a positive integer that is greater than 1, e.g., 2, 3, 4, or 5. Each lumped differential analog input buffer 12₁, . . . , 12_{K} may be low gain and low output impedance differential amplifiers, e.g., the differential amplifier 12A of FIG. 2A. Each SIHCOB stage 18₁, . . . , 18_{K} may have, e.g., the architecture of the SIHCOB 18 of FIG. 4. The distributed clock buffer 20′ includes two parallel pairs of substantially identical (K+1)-segment transmission lines (28_{P}, 28_{N}), (29_{P}, 29_{N}) and K lumped differential lumped clock cores 22₁, . . . , 22_{K}. Each differential lumped clock core 22₁, . . . , 22_{K} may be a saturated differential amplifier having the topology of the differential amplifier 12A of FIG. 12A. In the lumped clock cores 22₁, . . . , 22_{K}, the bias transistors R, R′ of FIG. 2A have values that cause the differential amplifier to have short rise and drop times in response to input clock signals CLK_{P}, CLK_{N}. Such short rise and drop times can decrease timing jitter. The various transmission lines 14_{P}, 14_{N}, 16_{P}, 16_{N} 26_{P}, 26_{N}, 28_{P}, 28_{N}, 29_{P}, 29_{N} are formed of substantially identical sequences of microstrip segments, MS, so that the K SIHCOB stages 18₁, . . . , 18_{K} can operate substantially in parallel in the DTHA 10′. In light of the above description, one of skill in the art would be able to fabricate the DTHA 10′ without the need to perform undue experimentation.

While the above description has described various components in terms of circuits involving bipolar transistors, the scope of the invention includes other embodiments wherein said circuits are replaced by functionally similar circuits that use field-effect transistors. For example, one of skill in the art would know how to substitute functionally similar or equivalent CMOS transistor circuits for one or more of the bipolar transistor circuits in the analog input buffer 12 and SICHOB stages 18₁, 18₂, 18₃ of FIG. 1; analog input buffers 12A, 12B of FIG. 2A and 2B; analog input buffer AIB, analog output buffer AOB, and clock of FIG. 3; SIHCOB stages 18 of FIG. 4; clock buffer 20 of FIG. 5; and input buffers 12₁-12_{K}, SIHCOB stages 18₁-18_{K}, and clock buffers 22₁-22_{K} of FIG. 7. In light of the above disclosure, such substitutions would not require undue experimentation to a person of ordinary skill in the art.

In other embodiments, differential circuit blocks, e.g., analog input and output buffers, SIHCOB stages, clocks and/or clock buffers, of FIGS. 1-5 and 7 may be replaced by non-differential circuit blocks and paired of transmission lines may be replaced by unpaired transmission lines. In light of the above disclosure, one of skill in the art would be able to produce such embodiments by making such a replacement without performing undue experimentation.

From the disclosure, drawings, and claims, other embodiments of the invention will be apparent to those skilled in the art.

What is claimed is:

1. An apparatus, comprising:
an analog input buffer having one or more inputs and one or more outputs;
a plurality of track-and-hold stages, each track-and-hold stage having one or more inputs and one or more outputs;
one or more input transmission lines connecting the one or more outputs of the differential analog input buffer to the inputs of the track-and-hold stages;
one or more output transmission lines connected to the outputs of the track-and-hold stages;
wherein connections to the inputs of the stages are spatially distributed along the one or more input transmission lines and connections to the outputs of the stages are spatially distributed along the one or more output transmission lines.

2. The apparatus of claim 1,
wherein the analog input buffer is differential and has a pair of inputs and a pair of outputs;
wherein each track-and-hold stage is a differential and has a pair of inputs and a pair of outputs; and
wherein the one or more input transmission lines includes a pair of input transmission lines and the one or more output transmission lines includes a pair of output transmission lines

3. The apparatus of claim 2, wherein each track-and-hold stage includes a pair of switched analog track stages and a corresponding pair of hold capacitors, each particular one of the track stages being configured to charge the corresponding pair of hold capacitors thereof in a manner indicative of signals received at the pair of inputs of the particular one of the track stages.

4. The apparatus of claim 3, further comprising a clock configured to generate operating signals for the track-and-hold stages, the clock including a pair of transmission lines.

5. The apparatus of claim 1, further comprising a clock configured to generate operating signals for the track-and-hold stages, the clock including one or more transmission lines.

6. The apparatus of claim 1, wherein each track-and-hold stage includes a switched analog track stage and a corresponding hold capacitor, each particular one of the track stages being configured to charge the corresponding one of the hold capacitors thereof in a manner indicative of signals received at the one or more inputs of the particular one of the track stages.

7. The apparatus of claim 6, each individual one of the track-and-hold stages further comprising an analog output buffer configured to generate signals indicative of charges stored on the hold capacitor corresponding to the individual one of the track-and-hold stages.

8. The apparatus of claim 6, wherein each switched analog track stage includes an emitter follower connected to charge the corresponding hold capacitor thereof.

9. The apparatus of claim 1, further comprising a clock configured to generate operating signals for the track-and-hold stages, the clock including a transmission line.

10. The apparatus of claim 1, wherein the input buffer and the stages include CMOS circuits.

11. A method of operating a track-and-hold amplifier, comprising:
transmitting an input waveform to one or more input transmission lines;
charging a plurality of hold capacitors by connecting the capacitors to points spatially distributed along the one or more input transmission lines while performing the transmitting; and
disconnecting the charged hold capacitors from the one or more input transmission lines such that the hold capacitors are connected along one or more output transmission lines.

12. The method of claim 11,
wherein the one or more input transmission lines includes a parallel pair of input transmission lines; and
wherein the one or more output transmission lines includes a parallel pair of output transmission lines.

13. The method of claim 12, further comprising:
sampling the pair of output transmission lines to measure a charge on the hold capacitors.

14. The method of claim 12, further comprising:
sampling signals via the pair of output transmission lines while the charged hold capacitors are disconnected from the pair of input transmission lines.

15. The method of claim 14, further comprising repeating the charging, disconnecting, and sampling steps to obtain a temporal sequence of digital measurements of the input waveform.

16. The method of claim 11, further comprising:
sampling the one or more output transmission lines to measure a charge on the hold capacitors.

17. The method of claim 16, further comprising repeating the charging, disconnecting, and sampling steps to obtain a temporal sequence of digital measurements of the input waveform.

18. The method of claim 16, wherein the sampling is performed while the hold capacitors are connected along the one or more output transmission lines.

19. The method of claim 11, wherein each capacitor receives the input waveform after a transmission delay, the transmission delay being substantially different for different ones of the capacitors.

20. The method of claim 19, wherein the input buffer and the stages include CMOS circuits.
